(19) United States
(12) Patent Application Publication
(10) Pub. No.: US 2025/0212625 A1
(43) Pub. Date: Jun. 26, 2025

(54) COVER AND DISPLAY MODULE

(71) Applicant: Shenzhen China Star Optoelectronics Semiconductor Display Technology Co., Ltd., Shenzhen (CN)

(72) Inventor: Yongsheng CHEN, Shenzhen (CN)

(73) Assignee: Shenzhen China Star Optoelectronics Semiconductor Display Technology Co., Ltd., Shenzhen (CN)

(21) Appl. No.: 18/963,739

(22) Filed: Nov. 28, 2024

(30) Foreign Application Priority Data
Dec. 21, 2023 (CN) 202311780729.0

(51) Int. Cl. H10K 59/126; H10K 59/80; H10K 102/00

(52) U.S. Cl. CPC H10K 59/126; H10K 59/873; H10K 2102/351

(57) ABSTRACT

Disclosed are a cover and a display module. The cover includes a first ink layer and a second ink layer. The first ink layer includes a first light-shielding area and a first light-transmitting area, and the second ink layer includes a second light-shielding area and a second light-transmitting area. An orthographic projection of the second light-shielding area on a cover body at least partially covers an orthographic projection of the first light-transmitting area on the cover body.

### CROSS-REFERENCE TO RELATED APPLICATIONS

This application claims priority to Chinese Patent Application No. 202311780729.0, filed on Dec. 21, 2023, the entire disclosure of which is incorporated herein by reference.

### TECHNICAL FIELD

The present disclosure relates to the field of display technology, and more particularly, to a cover and a display module.

### BACKGROUND

With the development of OLED technology, foldable mobile phones are gradually increasing in the development and application thereof. In order to meet the bending requirements, the modules of the foldable displays are generally made of an organic film material. A variety of inks are used in local areas of an organic cover to achieve shielding effect and to meet various requirements for various sensors, such as cameras, color temperature sensors, and IR range sensors. In order to improve the appearance effect, the integration degree of the inks in the hole area is improved to achieve a better appearance effect on the premise that the optical requirements are met. There may be overlapping areas between the different inks, so that the ink thicknesses of these overlapping areas to be different from those of other areas, resulting in apparent appearance imprints.

In addition, unevenness at the O-Cut ink holes also lead to an increase in a PV (Peak to Valley) value, further affecting the imaging resolution. At present, the solutions is to reduce the thicknesses of the inks to reduce the overall unevenness caused by the difference in ink thicknesses, thereby reducing the PV value. However, due to the limitation of the printing process, thinning of the ink thicknesses may lead to display problems such as jagged edges, light leakage, and substandard brightness in appearance.

### SUMMARY

The present disclosure provides a cover and a display module, which can solve the technical problem of poor display of the display module due to the difference in ink thicknesses.

According to a first aspect, the present disclosure provides a cover for use in a display module, the cover comprising:
a cover body;
a first ink layer covering a part of a surface of the cover body to form a first light-shielding area, wherein another part of the surface of the cover body not covered by the first ink layer forms a first light-transmitting area, and the first light-shielding area is disposed around at least a part of the first light-transmitting area;
a flexible support layer disposed on a side of the first ink layer away from the cover body; and
a second ink layer covering a part of a surface of the flexible support layer away from the cover body to form a second light-shielding area, wherein another part of the surface of the flexible support layer not covered by the second ink layer forms a second light-transmitting area, and the second light-shielding area is disposed around at least a part of the second light-transmitting area.

An orthographic projection of the second light-shielding area on the cover body at least partially covers an orthographic projection of the first light-transmitting area on the cover body.

Further, an orthographic projection of the second light-transmitting area on the cover body falls within a range of the orthographic projection of the first light-transmitting area on the cover body.
the orthographic projection of the second light-shielding area on the cover body partially or completely overlaps an orthographic projection of the first light-shielding area on the cover body.

Further, the first light-transmitting area comprises a first sub-light-transmitting area, the first ink layer comprises a first sub-ink layer, and the first sub-ink layer comprises a first light-transmitting hole disposed in the first sub-light-transmitting area;
the second light-transmitting area comprises a second sub-light-transmitting area, the second ink layer comprises a second sub-ink layer, and the second sub-ink layer comprises a second light-transmitting hole disposed in the second sub-light-transmitting area.

An orthographic projection of the second light-transmitting hole on the cover body falls within a range of the orthographic projection of the first light-transmitting hole.

Further, an aperture size L of the second light-transmitting hole satisfies L≤y≤L+2x−e, wherein x≥e, y is an aperture size of the first light-transmitting hole, x is a length of the second sub-ink layer, and e is an error value in a range of 0.1 to 0.2 mm.

Further, the first light-shielding area comprises a first sub-light-shielding area, the first sub-ink layer comprises a first light-shielding portion disposed in the first sub-light-shielding area; and
the second light-shielding area comprises a second sub-light-shielding area, the second sub-ink layer comprises a second light-shielding portion disposed in the second sub-light-shielding area.

An orthographic projection of the second light-shielding portion on the cover body falls within a range of the orthographic projection of the first light-shielding portion on the cover body.

Further, the first light-transmitting area comprises a third sub-light-transmitting area, the first ink layer comprises a third sub-ink layer, and the third sub-ink layer comprises a third light-transmitting hole disposed in the third sub-light-transmitting area;
the second light-transmitting area comprises a fourth sub-light-transmitting area, the second ink layer comprises a fourth sub-ink layer, and the fourth sub-ink layer comprises a fourth light-transmitting hole disposed in the fourth sub-light-transmitting area;
the first light-shielding area comprises a third sub-light-shielding area, and the third sub-ink layer comprises a third light-shielding portion disposed in the third sub-light-shielding area; and
the second light-shielding area comprises a fourth sub-light-shielding area, and the fourth sub-ink layer comprises a fourth light-shielding portion disposed in the fourth sub-light-shielding area.

An orthographic projection of the fourth light-shielding portion on the cover body completely overlaps an orthographic projection of the third light-transmitting hole on the cover body.

An orthographic projection of the fourth light-transmitting hole on the cover body completely overlaps an orthographic projection of the third light-shielding portion on the cover body.

Further, an aperture size k of the fourth light-shielding portion satisfies: K≥m+e, wherein m>0, m is an aperture size of the third light-transmitting hole, e is an error value in a range of 0.1 to 0.2 mm.

Further, the cover further comprises an adhesive layer disposed between the cover body and the flexible support layer and covering the first ink layer.

Further, the first ink layer has a thickness of 2 to 4 μm; and the second ink layer has a thickness of 2 to 3 μm.

According to another aspect, the present disclosure further provides a display module including a cover as described above, a bonding layer, and a display substrate, wherein the display substrate is adhered to the cover by the bonding layer.

### BRIEF DESCRIPTION OF THE DRAWINGS

The technical solutions and other beneficial effects of the present disclosure will be apparent from the following detailed description of specific embodiments thereof, taken in conjunction with the accompanying drawings.

FIG. 1 is a schematic diagram of a cover according to some embodiments of the present disclosure.

FIG. 2 is a plan view of a part of a cover according to some embodiments of the present disclosure.

FIG. 3 is an enlarged view of a first structure of A1 in FIG. 1.

FIG. 4 is an enlarged view of a second structure of A1 in FIG. 1.

FIG. 5 is an enlarged view of A2 in FIG. 1.

FIG. 6 is a schematic diagram of a display module according to some embodiment of the present disclosure.

### LIST OF REFERENCE SIGNS

100. Cover; 200. Bonding layer; 300. Display substrate; 1. Cover body; 2. First ink layer; 21. First sub-ink layer; 22. Third sub-ink layer; 211. First light-transmitting hole; 212. Third light-transmitting hole; 3. Adhesive layer; 4. Flexible support layer; 5. Second ink layer; 51. Second sub-ink layer; 52. Fourth sub-ink layer; 511. Second light-transmitting hole; 512. Fourth light-transmitting hole; P1. First hole area; P2. First hole area; 210. First light-shielding area; 201. First sub-light-shielding area; 2010. First light-shielding portion; 202. Third sub-light-shielding area; 2020. Third light-shielding portion; 220. First light-transmitting area; 221. First sub-light-transmitting area; 222. Third sub-light-transmitting area; 510. Second light-shielding area; 501. Second sub-light-shielding area; 5010. Second light-shielding portion; 502. Fourth sub-light-shielding area; 5020. Fourth light-shielding portion; 520. Second light-transmitting area; 521. Second sub-light-transmitting area; 522. Fourth sub-light-transmitting area.

### DETAILED DESCRIPTION

Embodiments of the present disclosure will be described with reference to the accompanying drawings. It will be apparent that the described embodiments are only part, rather than all, of the embodiments of the present disclosure. All other embodiments obtained by a person skilled in the art based on the embodiments in the present disclosure without involving any inventive effort, are within the scope of the present disclosure.

In the description of the present disclosure, it is to be understood that the terms “first” and “second” are used for descriptive purposes only, and do not intended to indicate or imply relative importance or to imply the number of listed technical features. Therefore, features defined by “first” or “second” can explicitly or implicitly include one or more of the features. In the description of the present disclosure, “plurality” means two or more, unless expressly and specifically defined otherwise.

In the present disclosure, unless expressly and specifically defined otherwise, a first feature being “on” or “below” a second feature may mean that the first feature is in direct contact with the second features, or the first feature is in contact with the second feature through another feature therebetween. In addition, the first feature being “on”, “above”, or “over” the second feature may mean that the first feature is directly above or obliquely above the second feature, or merely indicates that the first feature is higher in level than the second feature. The first feature being “below”, “under”, or “underneath” the second feature may mean that the first feature is directly below or obliquely below the second feature, or merely indicates that the first feature is lower in level than the second feature.

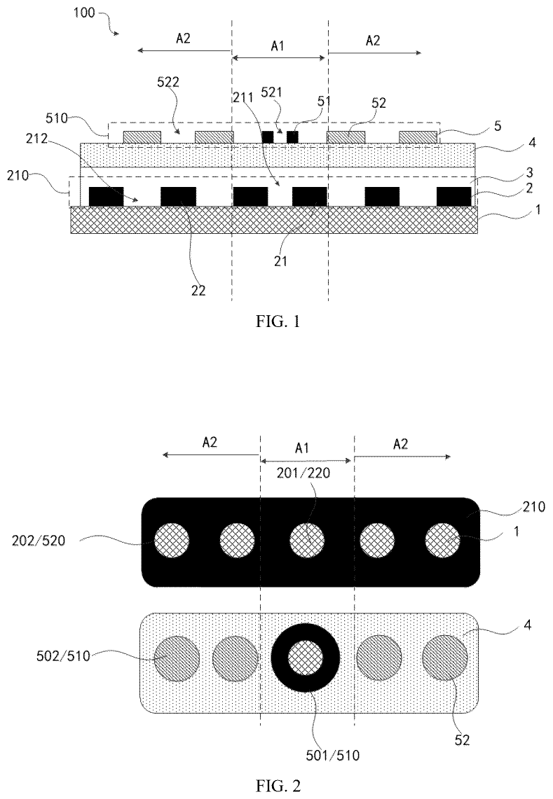

Referring to FIGS. 1 to 5, some embodiments of the present disclosure provide a cover 100 for use in a display module. The cover 100 includes a cover body 1, a first ink layer 2, an adhesive layer 3, a flexible support layer 4, and a second ink layer 5.

The first ink layer 2 covers a part of a surface (i.e., an upper surface) of the cover body 1 to form a first light-shielding area 210, and another part of the surface of the cover body 1 not covered by the first ink layer 2 forms a first light-transmitting area 220. The first light-shielding area 210 is disposed around at least a portion of the first light-transmitting area 220. The first ink layer 2 is made of a black ink, which can provide a shielding effect and meet the requirements of various sensors. The thickness of the first ink layer 2 is 2 to 4 μm, for example, 2.5 μm, 2.8 μm, 3 μm, 3.5 μm, 3.8 μm, or any value therebetween.

The flexible support layer 4 is disposed on a side of the first ink layer 2 away from the cover body 1. Specifically, the flexible support layer 4 is disposed above the first ink layer 2.

The flexible support layer 4 is an optical gasket made of an optical material. Specifically, the optical material includes, but is not limited to, an organic film material, a rubber-based material including but not limited to one of a polyurethane, an epoxy resin, and acrylic, or glass. When a camera is provided below the display module, a material with good light transmittance is selected for use as the optical gasket, so as to avoid the influence of the flexible support layer 4 on the camera. For example, an optical gasket with a light transmittance greater than 90%, a yellowness index less than 1, and a haze less than 1% is suitable.

The second ink layer 5 covers apart of a surface (i.e., an upper surface) of the flexible support layer 4 away from the cover body 1 to form a second light-shielding area 510, and another part of the surface of the flexible support layer 4 not covered by the second ink layer 5 forms a second light-transmitting area 520. The second light-transmitting area 520 is disposed around at least a portion of the second light-shielding area 510. The thickness of the second ink layer 5 is 2 to 3 μm, for example, 2.2 μm, 2.3 μm, 2.4 μm, 2.5 μm, 2.8 μm, 2.9 μm, or any value therebetween.

In some embodiments, the second ink layer 5 is made of a special ink, such as a red ink, a blue ink, a green ink, a black ink, a yellow ink, and the like. Specifically, one or more sensors, such as a camera, a color temperature sensor, and an IR range sensor, may be provided below the display module. The setting of the second ink layer 5 mainly depends on the requirements of the sensors, so that a certain light-shielding effect can be achieved, and the requirements of various sensors can be met. FIG. 1 illustrates a schematic diagram of a cover 100, in which a plurality of sensors are provided below the display module. The cover 100 includes an A1 area for a camera and an A2 area for the sensors other than the camera.

In some embodiments, the cover 100 further includes the adhesive layer 3 disposed between the cover body 1 and the flexible support layer 4 and covering the first ink layer 2. The adhesive layer 3 is a transparent optical adhesive layer with good light transmittance.

In some embodiments, an orthographic projection of the second light-shielding area 510 on the cover body 1 at least partially covers an orthographic projection of the first light-transmitting area 220 on the cover body 1. In this way, an orthographic projection of the first light-shielding area 210 and the orthographic projection of the second light-shielding area 510 on the cover body 1 can be arranged in a continuous manner, which can provide a good light-shielding effect, meet requirements for transmission of various optical sensors, while preventing the increase of PV value due to unevenness at the ink holes (light-transmitting holes).

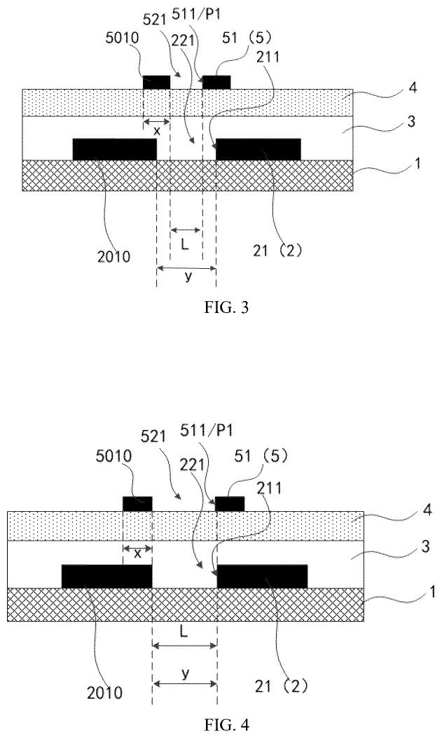

Referring to FIGS. 2 and 3, an orthographic projection of the second light-transmitting area 520 on the cover body 1 falls within the range of the orthographic projection of the first light-transmitting area 220 on the cover body 1, and the orthographic projection of the second light-shielding area 510 on the cover body 1 partially overlaps an orthographic projection of the first light-shielding area 210 on the cover body 1.

Referring to FIGS. 2 and 4, the orthographic projection of the second light-transmitting area 520 on the cover body 1 falls within the range of the orthographic projection of the first light-transmitting area 220 on the cover body 1, and the orthographic projection of the second light-shielding area 510 on the cover body 1 completely overlaps the orthographic projection of the first light-shielding area 210 on the cover body 1.

Referring to FIGS. 3 and 4, the first light-transmitting area 220 includes one or more first sub-light-transmitting areas 221. The first ink layer 2 includes a first sub-ink layer 21. The first sub-ink layer 21 includes one or more first light-transmitting holes 211 disposed in the corresponding first sub-light-transmitting area(s) 221. The first light-shielding area 210 includes one or more first sub-light-shielding areas 201, and the first sub-ink layer 21 includes one or more first light-shielding portions 2010 disposed in the corresponding first sub-light-shielding area(s) 201.

Referring to FIGS. 3 and 4, the second light-transmitting area 520 includes one or more second sub-light-transmitting areas 521. The second ink layer 5 includes a second sub-ink layer 51. The second sub-ink layer 51 includes one or more second light-transmitting holes 511 disposed in the corresponding second sub-light-transmitting area(s) 521. The second light-shielding area 510 includes one or more second sub-light-shielding areas 501, and the second sub-ink layer 51 includes one or more second light-shielding portions 5010 disposed in the corresponding second sub-light-shielding area(s) 501.

It is to be noted that the sensor(s) is generally provided below the cover 100 and corresponds to the second light-transmitting hole(s) 511. Accordingly, the cover 100 includes a first hole area corresponding to the sensor(s), and the sensor(s) is provided at a position corresponding to the first hole area of the cover 100.

Referring to FIGS. 3 and 4, the orthographic projection of the second light-transmitting hole 511 on the cover body 1 falls within the range of the orthographic projection of the first light-transmitting hole 211. That is, the aperture size of the second light-transmitting hole 511 may be less than or equal to the aperture size of the first light-transmitting hole 211. FIG. 3 shows a structure of the second light-transmitting hole 511 with an aperture size less than that of the first light-transmitting hole 211, and FIG. 4 shows a structure of the second light-transmitting hole 511 with an aperture size equal to that of the first light-transmitting hole 211.

Referring to FIGS. 3 and 4, an orthographic projection of the second light-shielding portions 5010 on the cover body 1 falls within the range of the orthographic projection of the first light-shielding portions 2010 on the cover body 1. FIG. 3 shows a structure in which the orthographic projection of the second light-shielding portions 5010 on the cover body 1 partially overlaps the orthographic projection of the first light-shielding portions 2010 on the cover body 1, and FIG. 4 shows a structure in which the orthographic projection of the second light-shielding portions 5010 on the cover body 1 completely overlaps the orthographic projection of the first light-shielding portions 2010 on the cover body 1.

Specifically, according to the embodiments of the present disclosure, the aperture size of each first light-transmitting hole 211 of the first sub-ink layer 21 generating a thickness difference is set to be larger than or equal to the aperture size of each second light-transmitting hole 511, so that PV/power value can be reduced, and the flatness and fitting of the cover body 1 and the flexible support layer 4 can be improved, thereby increasing the flatness range of the cover 100. In addition, the second sub-ink layer 51 is printed on the flexible support layer 4 to achieve a light-shielding effect. Since the second sub-ink layer 51 is not adhered to other parts by a glue, there is no thickness difference, preventing the cover 100 from being uneven, and the PV/Power value is not affected, yielding a good PV/Power value of the hole area.

In practical application, the aperture size of the first light-transmitting hole 211 of the first ink layer 2 generating the thickness difference is set to be larger than an aperture size of field of view (named “FOV aperture size” for short) of the camera, so that the flat area of the cover 100 covers the field of view of the camera, and the PV/power value is low. By printing the black ink on the flexible support layer 4 to form the second light-shielding portions 5010, the light-shielding effect is achieved, while avoiding the overall unevenness of the cover 100 due to the ink thickness difference. The aperture size of the camera may be less than or equal to the aperture size of the second light-transmitting hole 511.

It is to be understood that in the term of PV/power value, PV (Peak to Valley) means an optical path difference between peak and valley, the Power value indicates the degree to which the wave surface deviates from the flat plane, and both are optical indicators that characterize the flatness of the hole area.

The decrease of the PV/power value means, for all the ink holes (for example, the first light-transmitting hole 211 and the second light-transmitting hole 511), the more close to the ink, the more unevenness becomes, the more significant the test spot becomes, and the smaller the unevenness area becomes.

In some embodiments, the aperture size L of the second light-transmitting hole 511 satisfies: L≤y≤L+2x−e, where x≥e, y is the aperture size of the first light-transmitting hole 211, x is the length of the second sub-ink layer 51, and e is an error value in a range of 0.1 to 0.2 mm. In this way, the cover 100 has a good light-shielding effect while facilitating improvement of the flatness of the cover 100. When the camera is provided below the cover 100, the imaging resolution and the imaging quality can be improved. Therefore, the imprint and the PV/Power value of the first hole area are improved while the requirements for the transmission of the camera is satisfied.

Therefore, according to the embodiments of the present disclosure, a black ink is printed on the cover body 1 to form the first ink layer 2, various special inks are integrated on the flexible support layer 4 to form the second ink layer 5, and the ink holes (i.e., the light-transmitting holes) are designed, thereby avoiding appearance imprint caused by the existence of a large thickness difference in the ink overlap area. In addition, the ink in the imaging hole area is designed on the flexible support layer 4, avoiding the problem that the PV/power value does not meet the requirements due to the thickness difference of the ink.

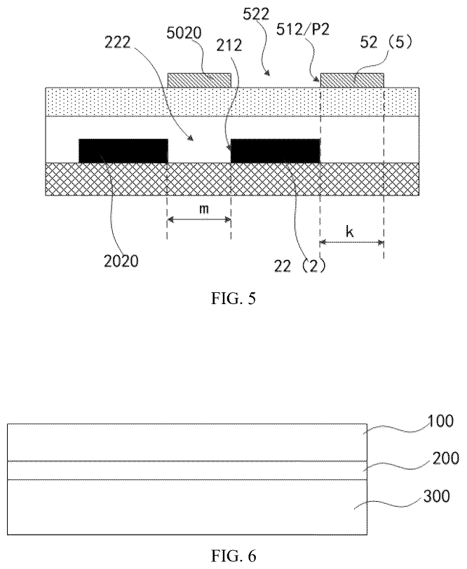

Referring to FIGS. 2 and 5, the first light-transmitting area 220 includes one or more third sub-light-transmitting areas 222. The first ink layer 2 includes a third sub-ink layer 22, and the third sub-ink layer 22 includes one or more third light-transmitting holes 212 disposed in the corresponding third sub-light-transmitting areas 222. The first light-shielding area 210 includes one or more third sub-light-shielding areas 202, and the third sub-ink layer 22 includes one or more third light-shielding portions 2020 disposed in the corresponding third sub-light-shielding areas 202.

The second light-transmitting area 520 includes one or more fourth sub-light-transmitting areas 522. The second ink layer 5 includes a fourth sub-ink layer 52, and the fourth sub-ink layer 52 includes one or more fourth light-transmitting holes 512 disposed in the corresponding fourth sub-light-transmitting areas 522. The second light-shielding area 510 includes one or more fourth sub-light-shielding areas 502, and the fourth sub-ink layer 52 includes one or more fourth light-shielding portions 5020 disposed in the corresponding fourth sub-light-shielding areas 502.

It is to be noted that the sensor(s) is generally provided below the cover 100 and corresponds to the fourth light-transmitting hole(s) 512. In this way, the cover 100 includes a second hole area corresponding to the sensor(s), and the sensor(s) is provided at a position corresponding to the second hole area of the cover 100.

An orthographic projection of the fourth light-shielding portions 5020 on the cover body 1 completely overlaps the orthographic projection of the third light-transmitting holes 212 on the cover body 1. An orthographic projection of the fourth light-transmitting holes 512 on the cover body 1 completely overlaps the orthographic projection of the third light-shielding portions 2020 on the cover body 1. That is, the orthographic projections of the third light-shielding portions 2020 and the fourth light-shielding portions 5020 on the cover main body 1 can be arranged in a continuous manner, so that the requirements of various optical sensors on the transmittance can be met while achieving a better light-shielding effect and avoiding the increase of the PV value due to unevenness at the ink holes (light-transmitting holes).

In some embodiments, the aperture size k of each fourth light-shielding portion 5020 satisfies: K≥m+e, where m>0, m is the aperture size of each third light-transmitting hole 212, and e is an error value in a range of 0.1 to 0.2 mm. In this way, the cover 100 has a good light-shielding effect, while improving the flatness of the cover 100, improving the imprint of the second hole area, optimizing the PV/Power value, and meeting the requirements for transmission of the sensors.

Referring to FIG. 6, some embodiments of the present disclosure further provides a display module including the cover 100 described above. The display module further includes a display substrate 300. The display substrate 300 is adhered to the cover 100 through a bonding layer 200. The bonding layer 200 is an OCA optical adhesive, so that the adhesive performance of the cover 100 and the display substrate 300 can be ensured. The display substrate 300 may include a backlight module, a display panel, a polarizer, and the like. Details are not described herein. The display module can have a better shielding effect, and can meet the requirements of various optical sensors for the transmittance, while avoiding the increase of the PV value due to unevenness at the ink holes.

The present disclosure have advantageous effects that in the cover and the display module, in which a first light-shielding area and a first light-transmitting area are formed on a first ink layer, and a second light-shielding area and a second light-transmitting area are formed on a second ink layer, wherein an orthographic projection of the second light-shielding area on a cover body at least partially covers the orthographic projection of the first light-transmitting area on the cover body, so that the orthographic projections of the first light-shielding area and the second light-shielding area on the cover body can be continuously arranged, so that an appearance mark can be avoided due to a large thickness difference of the ink overlapping area, and the requirements of various optical sensors on the transmittance can be met, and a problem that the PV value is increased due to unevenness of an ink hole can be avoided.

In the above-mentioned embodiments, the description of each embodiment has its own emphasis, and parts not described in detail in a certain embodiment may be referred to the related description in other embodiments.

The present disclosure has been described in detail with reference to the cover and the display module according to the embodiments of the present disclosure. Specific examples are used to illustrate the principles and implementations of the present disclosure. The description of the above embodiments is merely provided to help understand the technical solutions and the core idea of the present disclosure. It will be appreciated by those of ordinary skill in the art that modifications may still be made to the technical solutions described in the foregoing embodiments, or equivalent replacements may be made to some of the technical features therein. These modifications or replacements do not make the essence of the corresponding technical solutions deviate from the scope of the embodiments of the present disclosure.

What is claimed is:

1. A cover for use in a display module, the cover comprising:
a cover body;
a first ink layer covering a part of a surface of the cover body to form a first light-shielding area, wherein another part of the surface of the cover body not covered by the first ink layer forms a first light-transmitting area, and the first light-shielding area is disposed around at least a part of the first light-transmitting area;
a flexible support layer disposed on a side of the first ink layer away from the cover body; and
a second ink layer covering a part of a surface of the flexible support layer away from the cover body to form a second light-shielding area, wherein another part of the surface of the flexible support layer not covered by the second ink layer forms a second light-transmitting area, and the second light-shielding area is disposed around at least a part of the second light-transmitting area,
wherein an orthographic projection of the second light-shielding area on the cover body at least partially covers an orthographic projection of the first light-transmitting area on the cover body.

2. The cover according to claim 1, wherein
an orthographic projection of the second light-transmitting area on the cover body falls within a range of the orthographic projection of the first light-transmitting area on the cover body; and
the orthographic projection of the second light-shielding area on the cover body partially or completely overlaps an orthographic projection of the first light-shielding area on the cover body.

3. The cover according to claim 2, wherein the first light-transmitting area comprises a first sub-light-transmitting area, the first ink layer comprises a first sub-ink layer, and the first sub-ink layer comprises a first light-transmitting hole disposed in the first sub-light-transmitting area;
the second light-transmitting area comprises a second sub-light-transmitting area, the second ink layer comprises a second sub-ink layer, and the second sub-ink layer comprises a second light-transmitting hole disposed in the second sub-light-transmitting area;
the first light-shielding area comprises a first sub-light-shielding area, the first sub-ink layer comprises a first light-shielding portion disposed in the first sub-light-shielding area; and
the second light-shielding area comprises a second sub-light-shielding area, the second sub-ink layer comprises a second light-shielding portion disposed in the second sub-light-shielding area.

4. The cover according to claim 3, wherein an aperture size L of the second light-transmitting hole satisfies L≤y≤L+2x−e,
wherein x≥e, y is an aperture size of the first light-transmitting hole, x is a length of the second sub-ink layer, and e is an error value in a range of 0.1 to 0.2 mm.

5. The cover according to claim 3, wherein an orthographic projection of the second light-transmitting hole on the cover body falls within a range of an orthographic projection of the first light-transmitting hole; and
an orthographic projection of the second light-shielding portion on the cover body falls within a range of an orthographic projection of the first light-shielding portion on the cover body.

6. The cover according to claim 3, wherein the first light-transmitting area comprises a third sub-light-transmitting area, the first ink layer comprises a third sub-ink layer, and the third sub-ink layer comprises a third light-transmitting hole disposed in the third sub-light-transmitting area;
the second light-transmitting area comprises a fourth sub-light-transmitting area, the second ink layer comprises a fourth sub-ink layer, and the fourth sub-ink layer comprises a fourth light-transmitting hole disposed in the fourth sub-light-transmitting area;
the first light-shielding area comprises a third sub-light-shielding area, and the third sub-ink layer comprises a third light-shielding portion disposed in the third sub-light-shielding area; and
the second light-shielding area comprises a fourth sub-light-shielding area, and the fourth sub-ink layer comprises a fourth light-shielding portion disposed in the fourth sub-light-shielding area.

7. The cover according to claim 6, wherein an aperture size k of the fourth light-shielding portion satisfies: k≥m+e,
wherein m>0, m is an aperture size of the third light-transmitting hole, e is an error value in a range of 0.1 to 0.2 mm.

8. The cover according to claim 6, wherein an orthographic projection of the fourth light-shielding portion on the cover body completely covers an orthographic projection of the third light-transmitting hole on the cover body; and
an orthographic projection of the fourth light-transmitting hole on the cover body completely covers an orthographic projection of the third light-shielding portion on the cover body.

9. The cover according to claim 1, further comprising:
an adhesive layer disposed between the cover body and the flexible support layer and covering the first ink layer.

10. The cover according to claim 1, wherein the first ink layer has a thickness of 2 to 4 μm; and
the second ink layer has a thickness of 2 to 3 μm.

11. A display module comprising a cover, a bonding layer, and a display substrate, wherein the display substrate is adhered to the cover by the bonding layer, and
the cover comprises:
a cover body;
a first ink layer covering a part of a surface of the cover body to form a first light-shielding area, wherein another part of the surface of the cover body not covered by the first ink layer forms a first light-transmitting area, and the first light-shielding area is disposed around at least a part of the first light-transmitting area;
a flexible support layer disposed on a side of the first ink layer away from the cover body; and
a second ink layer covering a part of a surface of the flexible support layer away from the cover body to form a second light-shielding area, wherein another part of the surface of the flexible support layer not covered by the second ink layer forms a second light-transmitting area, and the second light-shielding area is disposed around at least a part of the second light-transmitting area,
wherein an orthographic projection of the second light-shielding area on the cover body at least partially covers an orthographic projection of the first light-transmitting area on the cover body.

12. The display module according to claim 11, wherein an orthographic projection of the second light-transmitting area on the cover body falls within a range of the orthographic projection of the first light-transmitting area on the cover body; and
the orthographic projection of the second light-shielding area on the cover body partially or completely overlaps an orthographic projection of the first light-shielding area on the cover body.

13. The display module according to claim 12, wherein the first light-transmitting area comprises a first sub-light-transmitting area, the first ink layer comprises a first sub-ink layer, and the first sub-ink layer comprises a first light-transmitting hole disposed in the first sub-light-transmitting area;
the second light-transmitting area comprises a second sub-light-transmitting area, the second ink layer comprises a second sub-ink layer, and the second sub-ink layer comprises a second light-transmitting holedisposed disposed in the second sub-light-transmitting area;
the first light-shielding area comprises a first sub-light-shielding area, the first sub-ink layer comprises a first light-shielding portion disposed in the first sub-light-shielding area; and
the second light-shielding area comprises a second sub-light-shielding area, the second sub-ink layer comprises a second light-shielding portion disposed in the second sub-light-shielding area.

14. The display module according to claim 13, wherein an aperture size L of the second light-transmitting hole satisfies L≤y≤L+2x−e,
wherein x≥e, y is an aperture size of the first light-transmitting hole, x is a length of the second sub-ink layer, and e is an error value in a range of 0.1 to 0.2 mm.

15. The display module according to claim 13, wherein an orthographic projection of the second light-transmitting hole on the cover body falls within a range of an orthographic projection of the first light-transmitting hole; and
an orthographic projection of the second light-shielding portion on the cover body falls within a range of an orthographic projection of the first light-shielding portion on the cover body.

16. The display module according to claim 13, wherein the first light-transmitting area comprises a third sub-light-transmitting area, the first ink layer comprises a third sub-ink layer, and the third sub-ink layer comprises a third light-transmitting hole disposed in the third sub-light-transmitting area;
the second light-transmitting area comprises a fourth sub-light-transmitting area, the second ink layer comprises a fourth sub-ink layer, and the fourth sub-ink layer comprises a fourth light-transmitting hole disposed in the fourth sub-light-transmitting area;
the first light-shielding area comprises a third sub-light-shielding area, and the third sub-ink layer comprises a third light-shielding portion disposed in the third sub-light-shielding area; and
the second light-shielding area comprises a fourth sub-light-shielding area, and the fourth sub-ink layer comprises a fourth light-shielding portion disposed in the fourth sub-light-shielding area.

17. The display module according to claim 16, wherein an aperture size k of the fourth light-shielding portion satisfies: k≥m+e,
wherein m>0, m is an aperture size of the third light-transmitting hole, e is an error value in a range of 0.1 to 0.2 mm.

18. The display module according to claim 16, wherein an orthographic projection of the fourth light-shielding portion on the cover body completely covers an orthographic projection of the third light-transmitting hole on the cover body; and
an orthographic projection of the fourth light-transmitting hole on the cover body completely covers an orthographic projection of the third light-shielding portion on the cover body.

19. The display module according to claim 11, further comprising:
an adhesive layer disposed between the cover body and the flexible support layer and covering the first ink layer.

20. The display module according to claim 11, wherein the first ink layer has a thickness of 2 to 4 μm; and
the second ink layer has a thickness of 2 to 3 μm.
